(19) United States
(12) Patent Application Publication
(10) Pub. No.: US 2026/0092807 A1
(43) Pub. Date: Apr. 2, 2026

(54) ABNORMAL SIGNAL DETECTION DEVICE USING DUAL ACOUSTIC WAVE SENSOR

(71) Applicant: MOVIC LAB INC., Incheon (KR)

(72) Inventor: Won Keun LEE, Incheon (KR)

(21) Appl. No.: 19/112,652

(22) PCT Filed: Nov. 24, 2022
(86) PCT No.: PCT/KR2022/018753

§ 371 Date: Mar. 18, 2025

(30) Foreign Application Priority Data
Oct. 26, 2022 (KR) 10-2022-0139605

(51) Int. Cl. G01H 1/14; B81B 3/00; G01D 11/24; G01H 11/08

(52) U.S. Cl. CPC G01H 1/14; B81B 3/0021; G01D 11/245; G01H 11/08; B81B 2201/0257

(57) ABSTRACT

The present application relates to an abnormal signal detection device using a dual acoustic wave sensor. The abnormal signal detection device using a dual acoustic wave sensor comprises: a housing including a first acoustic wave transmission portion and a second acoustic wave transmission portion; a base substrate located inside the housing and including a first surface and a second surface; a first acoustic wave sensor mounted on the first surface and converting an acoustic wave in a first band into a first electrical signal; a second acoustic wave sensor mounted on the second surface and converting an acoustic wave in a second band into a second electrical signal.

### TECHNICAL FIELD

The present disclosure relates to an abnormal signal detection device using a dual acoustic wave sensor, and more specifically, to an abnormal signal detection device using two acoustic wave sensors with different frequency detection ranges.

### BACKGROUND ART

Recently, predictive maintenance devices have been introduced that analyze information such as ultrasonic waves and vibrations to predict or detect equipment failures in advance. In the case of devices that analyze acoustic signals such as ultrasonic waves generated from equipment, a method of converting acoustic signals into electrical signals using a device such as a MEMS microphone or a condenser microphone is usually used.

However, to achieve higher accuracy, it is sometimes necessary to detect an acoustic signal in a wider frequency band. In such cases, when a single acoustic wave sensor is used, there is a limit to the frequency range that can ensure high sensitivity, so the sensitivity may be relatively low in some low-frequency or high-frequency ranges and low-magnitude signals may not be properly received.

Therefore, there is an increasing demand for devices capable of receiving acoustic waves in a wider frequency band while having a simple structure and efficiently processing signals.

### DISCLOSURE

### Technical Problem

An object of the present disclosure is to provide an abnormal signal detection device that receives acoustic waves in a wider frequency band while having a simple structure and efficiently processing signals.

In addition, an object of the present disclosure is to provide an abnormal signal detection device that generates a single combined signal upon receiving an acoustic wave using a dual acoustic wave sensor and analyzes the combined signal to determine whether there is an abnormality.

### Technical Solution

An abnormal signal detection device using a dual acoustic wave sensor according to one aspect of the present disclosure includes: a housing comprising a first acoustic wave transmission portion and a second acoustic wave transmission portion, and forming an internal space; a base substrate located inside the housing and comprising a first surface and a second surface, wherein the second surface is located to face the first and second acoustic wave transmission portions; a first acoustic wave sensor mounted on the first surface and converting an acoustic wave in a first band, introduced into the internal space through the first acoustic wave transmission portion, into a first electrical signal; a second acoustic wave sensor mounted on the second surface and converting an acoustic wave in a second band, introduced into the internal space through the second acoustic wave transmission portion, into a second electrical signal, wherein the second band has an overlapping band overlapping at least partially with the first band and has an intermediate frequency range corresponding to a frequency range lower than an intermediate frequency range of the first band; a signal combining unit coupled to the base substrate and generating a combined signal in which the first electrical signal and the second electrical signal are combined, wherein information on an overlapping band of the combined signal corresponds to a signal in which the first electrical signal and the second electrical signal are superimposed; and a determination unit comparing the combined signal with training data stored in a database to determine whether there is an abnormality, wherein the training data comprises abnormal signal data and normal signal data, wherein information on the overlapping band of the training data corresponds to a signal in which a first training signal of a first band and a second training signal of a second band are superimposed.

The abnormal signal detection device using a dual acoustic wave sensor according to one aspect of the present disclosure may further include a shield case coupled to the base substrate and covering the first acoustic wave sensor.

The shield case may be located apart from the housing.

The shield case may have a plurality of openings formed in an upper portion.

The first acoustic wave sensor may be a MEMS microphone.

The MEMS microphone may include: a microphone substrate coupled to the base substrate and having an acoustic hole formed therein; a transducer mounted on the microphone; and a cover coupled to the microphone substrate and accommodating the transducer, and an acoustic inlet hole may be formed in the base substrate to correspond to the acoustic hole.

The second acoustic wave sensor may be a piezoelectric element.

The second acoustic wave transmission portion may be formed in contact with a detection surface of the piezoelectric element and separated from portions of the housing in proximity of the second acoustic wave transmission portion.

The signal combining unit may be mounted on the first surface.

The first acoustic wave sensor may include a plurality of MEMS microphones spaced apart from each other.

The abnormal signal detection device using a dual acoustic wave sensor according to the above features may further include a shield case coupled to the base substrate and covering the first acoustic wave sensor, and the plurality of MEMS microphones may be covered by the shield case.

### Advantageous Effects

According to an abnormal signal detection device using a dual acoustic wave sensor of the present disclosure, there is an advantage of providing an abnormal signal detection device that receives an acoustic wave in a wider frequency band and while having a simple structure and efficiently processing signals.

In addition, according to an abnormal signal detection device using a dual acoustic wave sensor of the present disclosure, there is an advantage of providing an abnormal signal detection device that generates a single combined signal upon receiving an acoustic signal using a dual acoustic wave sensor and analyzes the combined signal to determine whether there is an abnormality in the combined signal.

### DESCRIPTION OF DRAWINGS

FIG. 1 is a block diagram of an abnormal signal detection device according to one embodiment of the present disclosure.

FIG. 2 is a cross-sectional drawing of an abnormal signal detection device according to one embodiment of the present disclosure.

FIG. 3 is a drawing illustrating a cross-section of a first acoustic wave sensor according to one embodiment of the present disclosure.

FIG. 4 is a drawing illustrating one side of an abnormal signal detection device according to one embodiment of the present disclosure.

FIG. 5 is a drawing illustrating another side of an abnormal signal detection device according to one embodiment of the present disclosure.

FIG. 6 is a graph illustrating first and second electrical signals and a combined signal generated by an abnormal signal detection device according to one embodiment of the present disclosure.

### BEST MODE FOR CARRYING OUT THE INVENTION

Hereinafter, embodiments disclosed in this specification will be described in detail with reference to the accompanying drawings, and the same or similar components may be provided with the same reference numbers and redundant descriptions thereof will be omitted. In addition, in describing embodiments disclosed in this specification, if it is determined that a detailed description of a related known technology may obscure the gist of the embodiments disclosed in this specification, the detailed description is omitted.

While terms including ordinal numbers, such as “first” and “second,” etc., may be used to describe various components, such components are not limited by the above terms. These terms are generally only used to distinguish one component from another.

Singular expressions include plural expressions unless clearly indicated otherwise by the context.

Each step described in this application may be performed in any order unless a specific sequence is required due to a clearly defined cause-and-effect relationship.

It will be understood that the terms used herein, such as “include” or “have”, specify the presence of stated features, integers, steps, operations, elements, and/or components, but do not preclude the presence or addition of one or more other features, integers, steps, operations, elements, components, and/or groups thereof.

Hereinafter, the present disclosure will be described with reference to the accompanying drawings.

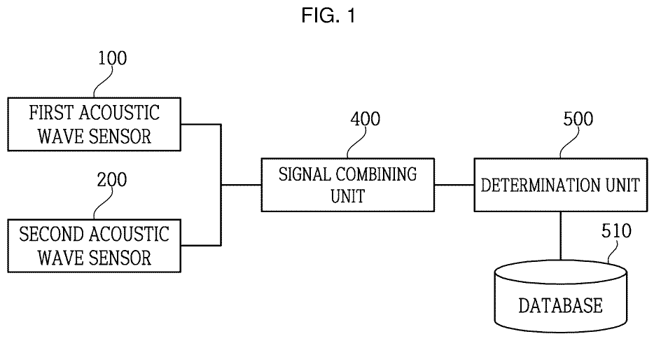

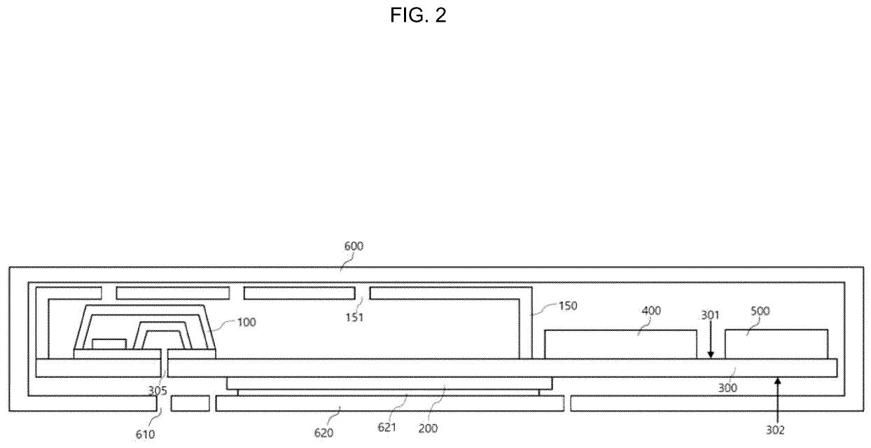

FIG. 1 is a block diagram of an abnormal signal detection device according to one embodiment of the present disclosure. FIG. 2 is a cross-sectional drawing of an abnormal signal detection device according to one embodiment of the present disclosure.

The abnormal signal detection device using a dual acoustic wave sensor of the present disclosure includes a housing 600, a base substrate 300, a first acoustic wave sensor 100, a second acoustic wave sensor 200, a signal combining unit 400, and a determination unit 500.

The housing 600 is a structure that forms an internal space. The housing 600 may include a first surface and a second surface. For example, when the housing 600 is formed as a hexahedron, the first surface and the second surface may be two surfaces facing each other.

The housing 600 includes a first acoustic wave transmission portion 610 and a second acoustic wave transmission portion 620. The first and second acoustic wave transmission portions 610, 620 are structures formed to transmit acoustic waves generated outside the housing 600 to the inside of the housing 600. The acoustic wave transmission portions may be formed, for example, as an opening or a vibration transmission plate.

The housing 600 may include a first surface and a second surface. For convenience of explanation, an upper surface of the housing 600 is referred to as the first surface and a lower surface is referred to as the second surface based on FIG. 2.

The first acoustic wave transmission portion 610 may be formed in the second surface of the housing 600. The first acoustic wave transmission portion 610 may be formed as an opening. Therefore, the first acoustic wave transmission portion 610 may introduce acoustic waves coming from a direction of the second surface into the internal space through the opening. Of course, the first acoustic wave transmission portion 610 may introduce acoustic waves coming from other directions as well as acoustic waves coming from the direction of the second surface into the internal space, but may introduce more acoustic waves coming from the direction of the second surface.

The second acoustic wave transmission portion 620 may be formed in the second surface of the housing 600. The second acoustic wave transmission portion 620 may be formed as a vibration transmission plate. Accordingly, the second acoustic wave transmission portion 620 may form vibrations by acoustic waves coming from the direction of the second surface and transmit the vibrations to an acoustic wave sensor. Of course, the second acoustic wave transmission portion 620 may transmit not only acoustic waves coming from the direction of the second surface but also acoustic waves coming from other directions, but it may transmit more acoustic signals coming from the direction of the second surface.

The second acoustic wave transmission portion 620 may be formed in contact with a detection surface of the second acoustic wave sensor 200 and may be separated from portions of the housing 600 in proximity of the second acoustic wave transmission portion 620. In some cases, a connecting contact member 621 may be additionally provided between the second acoustic wave transmission portion 620 and the detection surface of the second acoustic wave sensor 200.

Since the second acoustic wave transmission portion 620 is separated from portions of the housing 600 in proximity, the second acoustic wave transmission portion 620 may vibrate more effectively and transmit vibrations to the second acoustic wave sensor 200. In some cases, the second acoustic wave transmission portion 620 may maintain a predetermined gap with the portions of the housing 600 in proximity.

The first acoustic wave transmission portion 610 and the second acoustic wave transmission portion 620 may be located at a predetermined distance apart from each other on the same surface of the housing 600.

The base substrate 300 is a circuit board located inside the housing 600. The first acoustic wave sensor 100, the second acoustic wave sensor 200, and the signal combining unit 400, the determination unit 500, and a shield case 150 may be coupled to the base substrate 300.

The base substrate 300 is formed as a circuit board in the form of a flat plate, and includes a first surface 301 and a second surface 302, which correspond to opposite sides to each other. Here, the second surface 302 faces the first acoustic wave transmission portion 610 and the second acoustic wave transmission portion 620.

An acoustic inlet hole 305 corresponding to an acoustic hole 111 formed in a microphone substrate 110 of the first acoustic wave sensor 100 to be described may be formed in the base substrate 300.

The first acoustic wave sensor 100 is mounted on the first surface 301 of the base substrate 300. Also, the first acoustic wave sensor 100 may be located opposite to the first acoustic wave transmission portion 610 and may convert an acoustic wave in a first band, which is introduced into the internal space of the housing 600 through the first acoustic wave transmission portion 610, into a first electrical signal.

The first acoustic wave sensor 100 may be an acoustic wave sensor that is suitable for receiving an acoustic wave in a high-frequency band, compared to the second acoustic wave sensor 200 to be described. The first acoustic wave sensor 100 may be formed as a MEMS microphone.

The first acoustic wave sensor 100 may include a plurality of MEMS microphones. The plurality of MEMS microphones may be located to face in different directions, receiving acoustic signals transmitted from multiple directions. Directional characteristics may be achieved by using the plurality of MEMS microphones.

The second acoustic wave sensor 200 is mounted on the second surface 302 of the base substrate 300. Also, the second acoustic wave sensor 200 may be located opposite to the second acoustic wave transmission portion 620 and may convert an acoustic wave in a second band, which is introduced into the internal space of the housing 600 through the second acoustic wave transmission portion 620, into a second electrical signal.

The second acoustic wave sensor 200 may be an acoustic wave sensor that is suitable for receiving an acoustic wave in a low frequency band, compared to the first acoustic wave sensor 100 described above. The second acoustic wave sensor 200 may use a piezoelectric element rather than an acoustic wave sensor dedicated solely to sound reception. The entry element sensor has the advantage of superior sensitivity in a low frequency band compared to a sensor dedicated solely to sound reception, such as an MEMS microphone. However, since the piezoelectric element sensor requires a wider mounting area than the MEMS microphone, it may be desirable to mount only one piezoelectric element sensor on the base substrate 300.

The second band may include an overlapping band that overlaps at least partially with the first band. Also, an intermediate frequency range of the first band may be a higher frequency range than an intermediate frequency range of the second band.

The signal combining unit 400 is coupled to the base substrate 300 and generates a combined signal in which the first electrical signal and the second electrical signal are combined. Here, information on the overlapping band of the combined signal may correspond to a signal in which the first electrical signal and the second electrical signal are superimposed. If the first electrical signal and the second electrical signal are superimposed without scaling even though the overlapping band corresponds to both the first electrical signal and the second electrical signal, an absolute signal intensity of the overlapping band may be relatively greater than that of a non-overlapping band. However, in the present disclosure, the purpose of the combined signal is not to analyze an absolute signal intensity of a specific band, but to detect whether there is an abnormality through analysis of an abnormal signal and a normal signal. Therefore, if the abnormal signal and normal signal of training data to be compared have the same characteristics or types as those of a non-scaled combined signal described above, the abnormal signal and the normal signal may be compared with each other to detect whether there is an abnormality.

The determination unit 500 may be an element coupled to the base substrate 300, or may be an element present outside the housing 600 of the present disclosure and connected to the signal combining unit 400 by wire or via a network. The determination unit 500 compares a combined signal with training data stored in a database 510 to determine whether there is an abnormality. Here, the training data includes abnormal signal data and normal signal data. Also, information on an overlapping band for the training data may correspond to a signal in which a first training signal in the first band and a second training signal in the second band are superimposed. This means that since a combined signal and a signal of the training data have the same characteristics or types, it is possible to determine whether there is an abnormality through comparative analysis.

Referring to FIG. 2, the abnormal signal detection device of the present disclosure may further include the shield case 150.

The shield case 150 is a structure that is coupled to the base substrate 300 and covers the first acoustic wave sensor 100. The shield case 150 is connected to a grounding portion of the base substrate 300 to shield an external magnetic field, so that the first acoustic wave sensor 100 generates a first electrical signal without magnetic field noise. The shield case 150 may be located apart from the first surface of the housing 600. The shield case 150 may have a plurality of openings 151 formed in an upper portion.

When the first acoustic wave sensor 100 includes a plurality of MEMS microphones, the plurality of MEMS microphones spaced apart from each other may be all accommodated so as to be covered by one shield case 150.

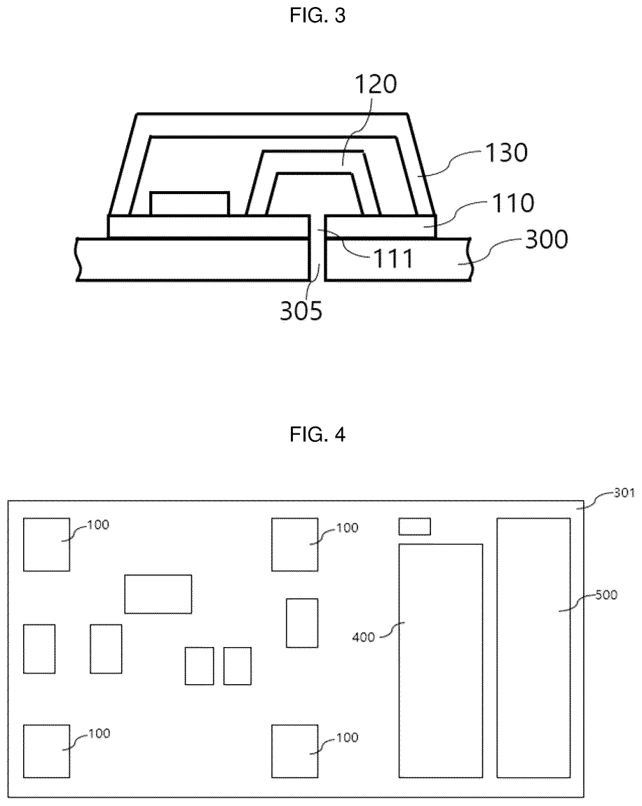

Hereinafter, the structure of the first acoustic wave sensor 100 will be described with reference to FIG. 3.

Specifically, the first acoustic wave sensor 100 may be formed as a rear-type MEMS microphone. The rear-type MEMS microphone is a MEMS microphone with an acoustic hole formed in a downward direction of a mounting surface.

The rear-type MEMS microphone includes a microphone substrate 110, a transducer 120, and a cover 110.

The microphone substrate 110 is a circuit board coupled to the base substrate 300. A signal transmission terminal is formed at a bottom of the microphone substrate 110 so that an electrical signal generated by the transducer 120 may be transmitted to the base substrate 300.

The microphone substrate 110 may have an acoustic hole 111 formed into which an acoustic signal detected by the transducer 120 is introduced. Also, an acoustic inlet hole 305 corresponding to an acoustic hole 111 formed in the microphone substrate 110 of a first acoustic wave sensor 100 to be described may be formed in the base substrate 300. The acoustic signal introduced into the housing 600 through the first acoustic wave transmission portion 610 passes through the acoustic inlet hole 305 and the acoustic hole 111 and is detected by the transducer 120.

The cover 130 is coupled to the microphone substrate 110 and accommodates the transducer 120. The cover 130 is formed as a metal can and is coupled to the microphone substrate 110.

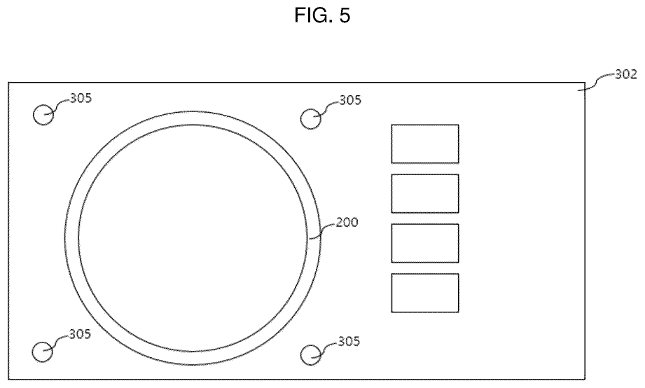

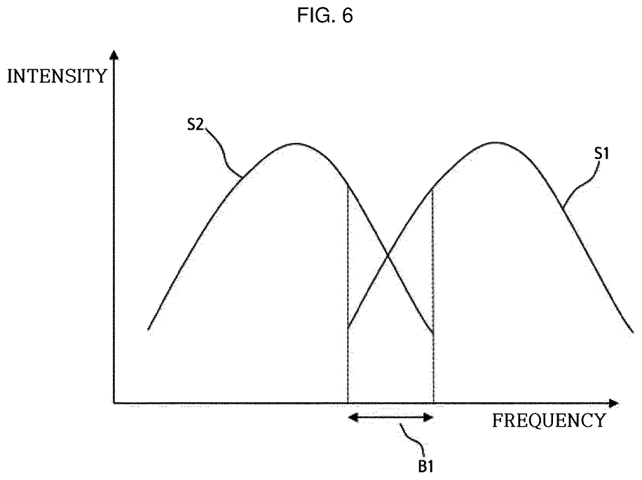

Hereinafter, how the base substrate is mounted will be described with reference to FIGS. 4 and 5.

As described above, the first acoustic wave sensor 100 and the signal combining unit 400 may be mounted on the first surface 301 of the base substrate 300. Since the first acoustic wave sensor 100 occupies a relatively small mounting area compared to the second acoustic wave sensor 200, the signal combining unit 400 may be located on the first surface 301.

A second acoustic wave sensor 200 may be mounted on the second surface 302 of the base substrate 300. Since the second acoustic wave sensor 200 occupies a relatively large mounting area compared to the first acoustic wave sensor 100, the signal combining unit 400 may be located on the second surface 302. Also, the second electrical signal generated by the second acoustic wave sensor 200 may be transmitted to the signal combining unit 400 of the first surface 301 through a via hole.

The acoustic inlet hole 305 may be located at a corner area of the second surface 302 of the base substrate 300, where the second acoustic wave sensor 200 is not located. In particular, the second acoustic wave sensor 200 may be formed in a circular shape, and the acoustic inlet hole 305 may be located in a space between the second acoustic wave sensor 200 and a corner of the base substrate 300.

Hereinafter, the first and second electrical signals and the combined signal generated by the abnormal signal detection device will be described with reference to FIG. 7.

The first electrical signal is a signal generated upon receiving an acoustic signal in a first band. The first band may be, for example, a frequency range of approximately 200 Hz or higher.

The second electrical signal is a signal generated upon receiving an acoustic signal in a second band. The second band may be, for example, a low-frequency range of 300 Hz or lower.

The first and second bands may form an overlapping band. Since the first and second electrical signals corresponding to the overlapping band overlap to become a combined signal, the magnitude of a signal in the overlapping band may be greater than the magnitude of a signal in an adjacent band.

However, training data to be compared with the combined signal is a signal in the overlapping band that corresponds to the sum of signals generated by the two acoustic wave sensors, so there may not be a problem in analyzing the combined signal and determining whether there is an abnormality.

The technical features disclosed in each embodiment of the present disclosure are not limited to a corresponding embodiment, and unless incompatible with each other, the technical features disclosed in each embodiment may be applied in combination to other embodiments.

Therefore, although each embodiment is described mainly about an individual technical feature, the technical features of the embodiments of the present disclosure may be applied in combination, unless incompatible with each other.

The present disclosure is not limited to the above-described embodiment and the accompanying drawings, and various modifications and changes may be made in view of the person skilled in the art to which the present disclosure pertains. The scope of the present disclosure should, therefore, be determined by equivalents to the claims, as well as by the claims of the present disclosure.

| | |
|---|---|
| 100: first acoustic wave sensor | 200: second acoustic wave sensor |
| 300: base substrate | 400: signal combining unit |
| 500: determination unit | 600: housing |

What is claimed is:

1. An abnormal signal detection device using a dual acoustic wave sensor, the abnormal signal detection device comprising:
a housing comprising a first acoustic wave transmission portion and a second acoustic wave transmission portion, and forming an internal space;
a base substrate, located inside the housing, comprising a first surface and a second surface, wherein the second surface is located to face the first acoustic wave transmission portion and the second acoustic wave transmission portion;
a first acoustic wave sensor mounted on the first surface and configured to convert an acoustic wave in a first band, introduced into the internal space through the first acoustic wave transmission portion, into a first electrical signal;
a second acoustic wave sensor mounted on the second surface and configured to convert an acoustic wave in a second band, introduced into the internal space through the second acoustic wave transmission portion, into a second electrical signal, wherein the second band has an overlapping band overlapping at least partially with the first band and has an intermediate frequency range corresponding to a frequency range lower than an intermediate frequency range of the first band;
a signal combining unit coupled to the base substrate and configured to generate a combined signal in which the first electrical signal and the second electrical signal are combined, wherein information on an overlapping band of the combined signal corresponds to a signal in which the first electrical signal and the second electrical signal are superimposed; and
a determination unit configured to compare the combined signal with training data stored in a database to determine whether there is an abnormality, wherein the training data comprises abnormal signal data and normal signal data,
wherein information on the overlapping band of the training data corresponds to a signal in which a first training signal of the first band and a second training signal of the second band are superimposed.

2. The abnormal signal detection device of claim 1, further comprising a shield case coupled to the base substrate and covering the first acoustic wave sensor.

3. The abnormal signal detection device of claim 2, wherein the shield case is located apart from the housing.

4. The abnormal signal detection device of claim 2, wherein the shield case has a plurality of openings formed in an upper portion.

5. The abnormal signal detection device of claim 1, wherein the first acoustic wave sensor is a MEMS microphone.

6. The abnormal signal detection device of claim 5, wherein the MEMS microphone comprises:
a microphone substrate coupled to the base substrate and having an acoustic hole formed therein;
a transducer mounted on the microphone; and
a cover coupled to the microphone substrate and accommodating the transducer,
wherein an acoustic inlet hole is formed in the base substrate to correspond to the acoustic hole.

7. The abnormal signal detection device of claim 1, wherein the second acoustic wave sensor is a piezoelectric element.

8. The abnormal signal detection device of claim 7, wherein the second acoustic wave transmission portion is formed in contact with a detection surface of the piezoelectric element and is separated from portions of the housing in proximity of the second acoustic wave transmission portion.

9. The abnormal signal detection device of claim 1, wherein the signal combining unit is mounted on the first surface.

10. The abnormal signal detection device of claim 1, wherein the first acoustic wave sensor comprises a plurality of MEMS microphones spaced apart from each other.

11. The abnormal signal detection device of claim 10, further comprising a shield case coupled to the base substrate and covering the first acoustic wave sensor,
wherein the plurality of MEMS microphones are covered by the shield case.
